(19) United States
(12) Patent Application Publication
(10) Pub. No.: US 2025/0026911 A1
(43) Pub. Date: Jan. 23, 2025

(54) LIQUID COMPOSITION, PREPREG, METAL SUBSTRATE WITH RESIN, WIRING BOARD, AND SILICA PARTICLES

(71) Applicants: AGC INC., Tokyo (JP); AGC SI-TECH CO., LTD., Kitakyushu-shi (JP)

(72) Inventor: Hiromichi KAMO, Chiyoda-ku (JP)

(73) Assignees: AGC INC., Tokyo (JP); AGC SI-TECH CO., LTD., Kitakyushu-shi (JP)

(21) Appl. No.: 18/909,117

(22) Filed: Oct. 8, 2024

Related U.S. Application Data
(63) Continuation of application No. PCT/JP2023/014000, filed on Apr. 4, 2023.

(30) Foreign Application Priority Data
Apr. 12, 2022 (JP) 2022-065665
Apr. 12, 2022 (JP) 2022-065910
Apr. 12, 2022 (JP) 2022-065911
Apr. 28, 2022 (JP) 2022-075145

(51) Int. Cl. C08K 3/36

(52) U.S. Cl. CPC C08K 3/36; C08K 2201/003; C08K 2201/006

(57) ABSTRACT

A liquid composition containing a thermosetting resin and silica particles, in which (1) the d50 and specific surface area of the silica particles are within a particular range, and the viscosity of the composition is within a particular range, (2) the d50 of the silica particles and the product of the specific surface area and the d50 are in particular ranges, and the liquid composition further contains a solvent having a specific surface tension, (3) the d50/d10 of the silica particles is in a particular range, the liquid composition further contains a solvent having a specific boiling point and a specific evaporation rate, and the thixotropy ratio of the composition is in a specific range, or (4) the proportion of silica particles having a particle diameter of 10 μm or more, the coefficient of variation of particle diameter, and the d50 are within particular ranges; and applications thereof.

### CROSS-REFERENCE TO RELATED APPLICATION

This application is a Continuation of International Application No. PCT/JP2023/014000, filed Apr. 4, 2023, which claims priority to Japanese Patent Application No. 2022-065910, filed on Apr. 12, 2022, Japanese Patent Application No. 2022-065911, filed on Apr. 12, 2022, Japanese Patent Application No. 2022-065665, filed on Apr. 12, 2022, and Japanese Patent Application No. 2022-075145 filed on Apr. 28, 2022. Each of the above applications is hereby expressly incorporated by reference, in its entirety, into the present application.

### TECHNICAL FIELD

The present disclosure relates to a liquid composition, a prepreg, a metal substrate with a resin, a wiring board, and silica particles.

### BACKGROUND ART

Liquid compositions containing thermosetting resin and silica particles are used to manufacture electrically insulating layers provided in metal-clad laminates that can be processed into printed wiring boards (see Patent Literatures 1 and 2). Specifically, metal-clad laminates in which a semi-cured product of a liquid composition is layered on the surface of a metal substrate layer as an electrically insulating layer, and metal-clad laminates in which a glass cloth or the like impregnated with the liquid composition is layered on the surface of a metal substrate layer as an electrically insulating layer, are used. In recent years, there has been a demand for electrically insulating layers of printed wiring boards to have improved properties such as a low dielectric constant, a low dielectric tangent, and a low linear expansion coefficient.

### CITATION LIST

### Patent Literature

Patent Literature 1: JP 2013-212956 A
Patent Literature 2: JP 2015-036357 A

### SUMMARY OF INVENTION

### Technical Problem

Meanwhile, from the viewpoint of reliability of wiring boards and the like, there is also a demand for a liquid composition used for forming an electrically insulating layer, such as a semi-cured product of the liquid composition or a glass cloth impregnated with the liquid composition, to have excellent adhesion to a metal substrate layer when cured. Although the silica particles contained in the liquid composition are expected to have the effect of improving the properties of the electrically insulating layer formed therefrom, the effect thereof on adhesion to the metal substrate layer has often been unclear.

The inventors found that, depending on the content of silica particles in a liquid composition and the physical properties of the silica particles, the physical properties of a semi-cured product of the liquid composition or the liquid composition in an impregnated state may change, and that the adhesion to a metal substrate layer may decrease.

An object of one embodiment of the present disclosure is to provide a liquid composition and a prepreg capable of forming a cured product that has excellent adhesion to a metal substrate layer. An object of one embodiment of the present disclosure is to provide a metal substrate with a resin and a wiring board, which have excellent adhesion between a liquid composition or a cured product thereof and a metal substrate layer. An object of one embodiment of the present disclosure is to provide silica particles that are used to adjust the viscosity of a liquid composition that has excellent adhesion to a metal substrate layer.

In addition, the inventors found that depending on the content of the silica particles in a liquid composition, the physical properties of the silica particles, and the shape of the silica particles, the silica particles may aggregate in the liquid composition, its semi-cured product, its cured product, or the like, resulting in uneven distribution of the silica particles, which may increase the water absorption rate of the semi-cured product, cured product, or the like, and reduce adhesion.

An object of one embodiment of the present disclosure is to provide a liquid composition capable of suppressing uneven distribution of silica particles and reducing the water absorption rate when formed into a cured product or the like, a prepreg, a metal substrate with a resin, and a wiring board. An object of one embodiment of the present disclosure is to provide silica particles that are used to adjust the viscosity of a liquid composition capable of suppressing uneven distribution of silica particles and reducing the water absorption rate when formed into a cured product or the like.

In a liquid composition containing a thermosetting resin and silica particles, there are cases in which the amount of silica particles added is increased in order to achieve a high filling rate, from the viewpoint of improving the low-dielectric properties, resistance to high temperature and high humidity, and the like, of the shaped material formed from the liquid composition. However, the inventors found that, in this case, the silica particles become more likely to aggregate, and the wettability of the silica particles by the liquid composition is decreased, whereby the properties of the silica particles may not be fully exhibited in the shaped material.

An object of one embodiment of the present disclosure is to provide a liquid composition capable of suppressing aggregation of silica particles, a prepreg, a metal substrate with a resin, and a wiring board using the liquid composition, and silica particles used for the liquid composition.

Further, in the case of producing a shaped material such as an electrically insulating layer using a liquid composition containing silica particles, it is preferable that the shaped material has a smooth surface from the viewpoint of reducing transmission loss or the like. However, there are cases in which the silica particles aggregate when the liquid composition is prepared, which affects the surface smoothness of the shaped material.

An object of one embodiment of the present disclosure is to provide a liquid composition capable of producing a shaped material having excellent surface smoothness, a prepreg, a metal substrate with a resin, and a wiring board using the liquid composition, and silica particles used for the liquid composition.

### Solution to Problem

The solution to the above-described problem includes the following aspects.
(1) A liquid composition, containing:
   a thermosetting resin; and
   silica particles having a median diameter d50 of from 0.5 to 20.0 μm and a specific surface area of from 0.1 to 3.5 m²/g,
   wherein the liquid composition has a viscosity of from 100 to 10000 mPa·s as measured at a rotation speed of 1 rpm at 25° C.
(2) The liquid composition according to (1), wherein an amount of the silica particles with respect to 100 parts by mass of the thermosetting resin is from 50 to 400 parts by mass.
(3) The liquid composition according to (1) or (2), further containing a solvent, wherein the solvent includes at least one selected from the group consisting of toluene, cyclohexanone, methyl ethyl ketone, and N-methyl-2-pyrrolidone.
(4) A liquid composition, containing:
   a thermosetting resin;
   silica particles having a median diameter d50 of from 0.5 to 20.0 μm, a product of a specific surface area thereof and a median diameter d50 thereof being from 2.7 to 5.0 μm·m²/g; and
   a solvent having a surface tension of 45 mN/m or less.
(5) The liquid composition according to (4), wherein the silica particles have a specific surface area of from 0.5 to 3.5 m²/g.
(6) The liquid composition according to (4) or (5), wherein an amount of the silica particles with respect to 100 parts by mass of the thermosetting resin is from 10 to 400 parts by mass.
(7) The liquid composition according to any one of (4) to (6), wherein the solvent includes at least one selected from the group consisting of toluene, cyclohexanone, methyl ethyl ketone, and N-methyl-2-pyrrolidone.
(8) A liquid composition, containing:
   a thermosetting resin;
   silica particles having a median diameter d50 of from 0.5 to 20.0 μm, a ratio of the median diameter d50 thereof to a 10% particle diameter d10 thereof being from more than 1.0 to 5.0; and
   a solvent having a boiling point of 75° C. or more and an evaporation rate based on butyl acetate of from 0.3 to 4.0,
   wherein a thixotropy ratio, calculated by dividing a viscosity of the liquid composition measured at a rotation speed of 1 rpm by a viscosity of the liquid composition measured at a rotation speed of 60 rpm, is 3.0 or less.
(9) The liquid composition according to (8), wherein a ratio of the median diameter d50 to the 10% particle diameter d10 of the silica particles is from 1.2 to 2.4.
(10) The liquid composition according to (8) or (9), wherein an amount of the silica particles with respect to 100 parts by mass of the thermosetting resin is from 10 to 400 parts by mass.
(11) The liquid composition according to any one of (8) to (10), wherein the solvent includes at least one selected from the group consisting of toluene, cyclohexanone, methyl ethyl ketone, and N-methyl-2-pyrrolidone.
(12) A liquid composition, containing:
   a thermosetting resin; and
   silica particles, wherein, in a particle size distribution obtained by a Coulter counter method, a proportion of particles having a particle diameter of 10 μm or more is 500 ppm by number or less, a coefficient of variation of particle diameter is from 30% to 80%, and a median diameter d50 is from more than 1.0 μm to 5.0 μm.
(13) The liquid composition according to (12), wherein the silica particles have a specific surface area of from 0.1 to 5.0 m²/g.
(14) The liquid composition according to (12) or (13), wherein the proportion of particles having a particle diameter of 10 μm or more in the silica particles is 300 ppm by number or less.
(15) The liquid composition according to any one of (12) to (14), further containing at least one solvent selected from the group consisting of toluene, methyl ethyl ketone, and N-methylpyrrolidone.
(16) The liquid composition according to any one of (12) to (15), wherein an amount of the silica particles with respect to 100 parts by mass of the thermosetting resin is from 10 to 400 parts by mass.
(17) The liquid composition according to any one of (1) to (16), wherein the thermosetting resin is an epoxy resin, a polyphenylene ether resin, or an ortho-divinylbenzene resin.
(18) A prepreg, including:
   the liquid composition according to any one of (1) to (16) or a semi-cured product thereof; and
   a fibrous substrate.
(19) A metal substrate with a resin including:
   the liquid composition according to any one of (1) to (16) or a semi-cured product thereof, or the prepreg according to (18); and
   a metal substrate layer.
(20) The metal substrate with a resin according to (19), wherein the metal substrate layer is a copper foil.
(21) The metal substrate with a resin according to (20), wherein a surface of the copper foil facing the liquid composition, the semi-cured product, or the prepreg has a maximum height roughness Rz of 2 μm or less.
(22) A wiring board, including:
   a cured product of the liquid composition according to any one of (1) to (16); and
   a metal wiring.
(23) Silica particles, having a median diameter d50 of from 0.5 to 20.0 μm and a specific surface area of from 0.1 to 3.5 m²/g, wherein the silica particles are used for adjusting a viscosity of a liquid composition containing a thermosetting resin.
(24) The silica particles according to (23), having a specific surface area of from 0.8 to 2.0 m²/g.
(25) Silica particles, having a median diameter d50 of from 0.5 to 20 μm, a product of a specific surface area thereof and a median diameter d50 thereof being from 2.7 to 5.0 μm·m²/g, wherein the silica particles are used to be added to a liquid composition containing a thermosetting resin.
(26) The silica particles according to (25), having a specific surface area of from 0.5 to 3.5 m²/g.
(27) Silica particles, having a median diameter d50 of from 0.5 to 20.0 μm, a ratio of a median diameter d50 thereof to a 10% particle diameter d10 thereof being from more than 1 to 5, wherein the silica particles are used for adjusting a thixotropy of a liquid composition containing a thermosetting resin.
(28) The silica particles according to (27), wherein the ratio is from 1.2 to 2.4.
(29) Silica particles, wherein:
   in a particle size distribution obtained by a Coulter counter method, a proportion of particles having a particle diameter of 10 μm or more is 500 ppm by number or less, a coefficient of variation of particle diameter is from 0.30 to 0.80, and a median diameter d50 is from more than 1.0 μm to 5.0 μm; and
   the silica particles are used to be mixed with a liquid composition containing a thermosetting resin, thereby forming a prepreg.
(30) The silica particles according to (29), having a specific surface area of from 0.1 to 5.0 m²/g.

### Advantageous Effects of Invention

According to one embodiment of the present disclosure, a liquid composition and a prepreg that exhibit excellent adhesion to a metal substrate layer when formed into a cured product are provided. According to one embodiment of the present disclosure, a metal substrate with a resin and a wiring board, which have excellent adhesion between a liquid composition or a cured product thereof and a metal substrate layer, are provided. According to one embodiment of the present disclosure, silica particles that are used to adjust the viscosity of a liquid composition that has excellent adhesion to a metal substrate layer are provided.

According to one embodiment of the present disclosure, a liquid composition capable of suppressing uneven distribution of silica particles and reducing the water absorption rate of a cured product or the like, a prepreg, a metal substrate with a resin, and a wiring board are provided. According to one embodiment of the present disclosure, silica particles that are used to adjust the viscosity of a liquid composition capable of suppressing uneven distribution of silica particles and reducing the water absorption rate of a cured product or the like are provided.

According to one embodiment of the present disclosure, a liquid composition capable of suppressing aggregation of silica particles, a prepreg, a metal substrate with a resin, and a wiring board using the liquid composition, and silica particles used for the liquid composition are provided.

According to one embodiment of the present disclosure, a liquid composition capable of producing a shaped material having excellent surface smoothness, a prepreg, a metal substrate with a resin, and a wiring board using the liquid composition, and silica particles used for the liquid composition are provided.

### DESCRIPTION OF EMBODIMENTS

Hereinafter, embodiments of the present disclosure will be described in detail. However, embodiments of the present disclosure are not limited to the following embodiments. Components (including element steps and the like) in the following embodiments are not essential unless otherwise specified. The same applies to numerical values and their ranges, and the numerical values and their ranges do not limit the embodiments of the present disclosure.

In the present disclosure, numerical ranges indicated using “to” includes the numerical values described before and after “to” as the minimum value and the maximum value, respectively.

In the present disclosure, each component may contain plural kinds of corresponding substances. In a case in which plural kinds of substances corresponding to a component are present in the composition, the content or amount of the component means the total content or amount of the plural kinds of substances present in the composition unless otherwise specified.

In the present disclosure, plural kinds of particles corresponding to a component may be contained. When plural kinds of particles corresponding to a component are present in a composition, the particle diameter of the component means a value for the mixture of the plural kinds of particles present in the composition unless otherwise specified.

In the present disclosure, “silica particles” refers to a group of silica particles unless otherwise specified.

In the present disclosure, the “median diameter d50 (hereinafter, also simply referred to as “d50”)” in the description of the particles contained in present compositions 1 to 3 described later is a volume-based cumulative 50% diameter of the particles determined using a laser diffraction particle size distribution measuring device (e.g., “MT3300EXII” manufactured by MicrotracBEL Corp.). In other words, it is a particle diameter at which the cumulative volume on a cumulative curve, obtained by determining the particle size distribution by a laser diffraction/scattering method, is 50%, the entire volume of the particles being set to 100%.

In the present disclosure, d50 in the description of the particles contained in present composition 4 described later is a volume-based cumulative 50% diameter of the silica particles obtained from the volume-based particle size distribution obtained by a Coulter counter method.

In the disclosure, “10% particle diameter d10” (hereinafter, also simply referred to as “d10”) in the description of the particles contained in the present compositions 1 to 3 described later is a volume-based cumulative 10% diameter of the particles determined using a laser diffraction particle size distribution measuring device (e.g., “MT3300EXII” manufactured by MicrotracBEL Corp.). In other words, it is a particle diameter at which the cumulative volume on a cumulative curve, obtained by determining the particle size distribution by a laser diffraction/scattering method, is 10%, the entire volume of the particles being set to 100%.

In the present disclosure, d10 in the description of the particles contained in the present composition 4 described later is a volume-based cumulative 10% diameter of the silica particles obtained from the volume-based particle size distribution obtained by the Coulter counter method.

In the present disclosure, the “proportion of particles having a particle diameter of 10 μm or more” is a proportion of particles determined from a number-based particle size distribution obtained by the Coulter counter method. Of 50,000 particles, the number of particles having a particle diameter of 10 μm or more is calculated, and the ratio of the particles having a particle diameter of 10 μm or more to the total number of measured particles (ppm by number) is determined.

In the present disclosure, the “coefficient of variation” (hereinafter also referred to as “CV value”) of particle diameter is an index of relative variation in the particle diameter, and is expressed as a percentage obtained by dividing the standard deviation of the particle diameter by the average particle diameter (d50 of particle diameter). The standard deviation of the particle diameter and the average particle diameter are determined from the volume-based particle size distribution obtained by the Coulter counter method.

The Coulter counter method is performed, for example, using a precision particle size distribution measuring device, Multisizer 4e, manufactured by Beckman Coulter.

In the present disclosure, the “specific surface area” is determined by the BET method based on the nitrogen adsorption method using a specific surface area/pore distribution measuring device (e.g., “Tristar II” manufactured by Micromeritics Instrument Corporation).

In the present disclosure, the “sphericity” refers to an average value obtained by measuring the maximum diameter (DL) and the minor axis (DS) perpendicular to the maximum diameter (DL) of each of 100 random particles in a photographic projection obtained by photographing the particles with a scanning electron microscope (SEM) and calculating the ratio (DS/DL) of the minor axis (DS) to the maximum diameter (DL).

In the present disclosure, the “dielectric tangent” and “dielectric constant” are measured by a perturbation resonator method using a dedicated device (e.g., the “Vector Network Analyzer E5063A” manufactured by KEYCOM Corporation).

In the present disclosure, the “viscosity” refers to a viscosity at 30 seconds measured at 25° C. for 30 seconds using a rotational rheometer (e.g., Modular Rheometer Physica MCR-301 manufactured by Anton Paar) at a shear rate of 1 rpm.

In the present disclosure, the “thixotropy ratio” is calculated by dividing the viscosity measured at a rotation speed of 1 rpm by the viscosity measured at a rotation speed of 60 rpm using a rotational rheometer.

In the present disclosure, the “weight average molecular weight” is determined using gel permeation chromatography (GPC) in terms of polystyrene.

In the present disclosure, the “surface tension” is measured by the Wilhelmy method using a surface tensiometer for a solvent at 25° C.

In the present disclosure, the “boiling point” is a boiling point at a normal pressure of 1.013×10⁵ Pa.

In the present disclosure, the “evaporation rate” is a relative evaporation rate when the evaporation rate of butyl acetate at 23° C. is set to 1.

In the present disclosure, the “liquid composition” refers to a composition that is liquid at 25° C.

In the present disclosure, the “semi-cured product” refers to a cured product of a liquid composition in a state in which an exothermic peak associated with curing of a thermosetting resin appears when the cured product of the liquid composition is measured by differential scanning calorimetry. In other words, the “semi-cured product” refers to a cured product in which an uncured thermosetting resin remains.

In the present disclosure, the “cured product” refers to a cured product of a liquid composition in a state in which an exothermic peak associated with curing of a thermosetting resin does not appear when the cured product of the liquid composition is measured by differential scanning calorimetry. In other words, the “cured product” refers to a cured product in which an uncured thermosetting resin does not remain.

In the present disclosure, the maximum height roughness Rz is measured in accordance with JIS B 0601 (2013).

In the present disclosure, the ten-point average roughness Rzjis is measured in accordance with the ten-point average roughness Rz of JIS B 0601 (1994).

A liquid composition 1 according to the present disclosure (hereinafter also referred to as “present composition 1”) contains: a thermosetting resin; and silica particles having a d50 of from 0.5 to 20 μm and a specific surface area of from 0.1 to 3.5 m²/g, and has a viscosity of 100 to 10000 mPa·s as measured at a rotation speed of 1 rpm at 25° C. In other words, the present composition 1 is a liquid thermosetting composition.

A liquid composition 2 according to the present disclosure (hereinafter also referred to as “present composition 2”) contains: a thermosetting resin; silica particles having a d50 of from 0.5 to 20.0 μm, the product of the specific surface area and d50 thereof being from 2.7 to 5.0 μm·m²/g; and a solvent having a surface tension of 45 mN/m or less. In other words, the present composition 2 is a liquid thermosetting composition.

A liquid composition 3 according to the present disclosure (hereinafter also referred to as “present composition 3”) contains: a thermosetting resin; silica particles having a d50 of from 0.5 to 20.0 μm, the ratio of d50 to d10 thereof (hereinafter also referred to as “d50/d10”) being from more than 1.0 to 5.0; and a solvent having a boiling point of 75° C. or more and an evaporation rate of from 0.3 to 4.0, the liquid composition having a thixotropy ratio of 3.0 or less. In other words, the present composition 3 is a liquid thermosetting composition.

A liquid composition 4 according to the present disclosure (hereinafter also referred to as “present composition 4”) contains: a thermosetting resin; and silica particles, wherein, in a particle size distribution obtained by a Coulter counter method, the proportion of particles having a particle diameter of 10 μm or more is 500 ppm by number or less, the coefficient of variation of particle diameter is from 30% to 80%, and the median diameter d50 is from more than 1.0 μm to 5.0 μm. In other words, the present composition 4 is a liquid thermosetting composition.

The present composition 1 is excellent in adhesion to a metal substrate layer. Although its mechanism of action is unclear, it is briefly estimated to be as follows. The present composition 1 contains silica particles having a d50 and a specific surface area within particular ranges. This improves the wettability of the silica particles contained in the present composition 1 and suppresses their aggregation, thereby improving the uniform dispersion of the silica particles in the present composition 1 and converging the viscosity of the composition within a certain range. It is believed that the use of the present composition 1 containing silica particles in such a state promotes the formation of a cured product in which the uneven distribution of silica particles is suppressed, in other words, a cured product in which the silica particles are not excessively exposed on the surface. As a result, it is believed that the adhesion of a cured product obtained from the present composition 1 to a metal substrate layer is improved. Hereinafter, the adhesion to a metal substrate layer will simply be referred to as “adhesion”.

The present composition 2 can suppress the uneven distribution of silica particles and reduce the water absorption rate of the cured product or the like. Although its mechanism of action is unclear, it is briefly estimated to be as follows. The silica particles in the present composition 2 have a d50 in a specific range (from 0.5 to 20.0 μm) and a product of the specific surface area and d50 in a particular range (from 2.7 to 5.0 μm·m²/g). In other words, the silica particles in the present composition 2 can be regarded as silica particles having a dense shape, a large specific surface area per unit mass, and a particle diameter on the μm scale. When such silica particles are interacted with a solvent having a predetermined low surface tension, it is believed that the silica particles are highly uniformly dispersed in the composition owing to the balance between the wettability of the silica particles caused by the specific surface area and the dispersion caused by the particle diameter. As a result, it is presumed that uneven distribution of the silica particles is suppressed in the present composition 2, a cured product thereof or the like, thereby reducing the water absorption rate of the cured product.

The present composition 3 has been found to exhibit high flowability and impregnating ability owing to suppressed aggregation of silica particles even after being heated to be used, whereby a shaped material formed therefrom can exhibit excellent silica characteristics. Although the reason for this is not entirely clear, it is presumed to be as follows. A low-viscosity solvent is considered to be advantageous for high filling of silica particles since it improves the wettability of the fine particle fraction (d10 portion) of the silica particles. However, it is believed that, if there is a large amount of the fine particle fraction of silica particles, evaporation of the solvent during heating becomes slow, which induces the aggregation of the silica particles, and that, as a result, the silica properties of the shaped material cannot be sufficiently improved. On the other hand, in the present composition 3, the d50/d10 of the silica particles is from more than 1.0 to 5.0, the evaporation rate of the solvent is within a specified range, and the thixotropy ratio is adjusted to be within a specified range. In other words, in the present composition 3, the filling property of the silica particles and the volatility of the solvent are well balanced. It is believed that that this suppresses the aggregation of the silica particles in the present composition 3, and that, therefore, even when the present composition 3 is heated to form a shaped material, the aggregation or segregation of the silica particles in the shaped material is suppressed, resulting in a shaped material in which the properties of the silica particles are favorably exhibited.

The present composition 4 is capable of forming a shaped material having excellent surface smoothness. Although the reason for this is not entirely clear, it is presumed to be as follows. The silica particles in the present composition 4 are silica particles having a certain particle distribution with particles of the μm order being the main particles, and can be regarded as silica particles in which the proportion of coarse particles is highly suppressed, and fine particles are contained at a certain proportion. It is believed that, by mixing such silica particles with a thermosetting resin to prepare a liquid composition, uneven distribution of the silica particles in the liquid composition due to aggregation of the fine particles themselves and aggregation of silica particles with coarse particles present as nuclei can be suppressed. In addition, it is believed that the fine particles improve the dispersion of the main particles and improve the interaction between the silica particles and the thermosetting resin. Furthermore, it is believed that, when a shaped material is formed from the liquid composition in such a state, the fine particles fill the gaps between the main particles to form a shaped material, which improves the surface smoothness of the shaped material. Furthermore, it is believed that, according to the present composition 4, it is possible to achieve high filling while suppressing aggregation of the silica particles, and that, therefore, the physical properties of the silica are favorably expressed in the shaped material.

The viscosity of the present composition 1 measured at a rotation speed of 1 rpm is from 100 to 10000 mPa·s, preferably from 130 to 5000 mPa·s, more preferably from 150 to 3000 mPa·s, still more preferably from 180 to 1500 mPa·s, and particularly preferably from 200 to 1000 mPa·s. When the viscosity falls within these ranges, the aggregation of the silica particles can be suppressed more effectively.

The viscosity of each of the present compositions 2 and 3 measured at a rotation speed of 1 rpm is preferably from 100 to 10000 mPa·s, more preferably from 130 to 5000 mPa·s, still more preferably from 150 to 3000 mPa·s, particularly preferably from 180 to 1500 mPa·s, and most preferably from 200 to 1000 mPa·s. When the viscosity falls within these ranges, the aggregation of the silica particles can be suppressed more effectively.

The viscosity of the present composition 4 measured at a rotation speed of 1 rpm is preferably from 130 to 5000 mPa·s, more preferably from 150 to 3000 mPa·s, still more preferably from 180 to 1500 mPa·s, and particularly preferably from 200 to 1000 mPa·s. When the viscosity falls within these ranges, the aggregation of the silica particles can be suppressed more effectively.

The thixotropy ratio of each of the present compositions 1, 2, and 4 is preferably 3.0 or less, more preferably 2.5 or less, and still more preferably 2.0 or less. The lower limit of the thixotropy ratio is not particularly limited, and may be 0.5 or more. When the thixotropy ratio is within these ranges, ease of storage, state stability, and flowability during use, of the present composition 1, 2, and 4 are favorable.

The thixotropy ratio of the present composition 3 is 3.0 or less. From the viewpoint of more favorably suppressing the aggregation of the silica particles, the thixotropy ratio is preferably 2.5 or less, and more preferably 2.0 or less. The lower limit of the thixotropy ratio is not particularly limited and may be 1.0. When the thixotropy ratio is within these ranges, ease of storage, state stability, and flowability during use, of the present composition 3 are favorable.

The present compositions 1, 2, 3, and 4 contain a thermosetting resin. For each composition, one type of thermosetting resin may be used singly, or two or more types thereof may be used in combination. Examples of the thermosetting resin include an epoxy resin, a polyphenylene ether resin, a polyimide resin, a phenol resin, and an ortho-divinylbenzene resin. From the viewpoint of adhesion, heat resistance, and the like, the thermosetting resin is preferably an epoxy resin, a polyphenylene ether resin, or an ortho-divinylbenzene resin. The thermosetting resin is preferably a resin containing at least one selected from the group consisting of a phenyl group and a phenylene group.

Examples of the epoxy resin include a bisphenol A-type epoxy resin, a bisphenol F-type epoxy resin, a bisphenol S-type epoxy resin, an alicyclic epoxy resin, a phenol novolac-type epoxy resin, a cresol novolac-type epoxy resin, a bisphenol A novolac-type epoxy resin, a diglycidyl-etherified product of a polyfunctional phenol, and a diglycidyl-etherified product of a polyfunctional alcohol.

The polyphenylene ether resin may be either a modified polyphenylene ether or an unmodified polyphenylene ether. From the viewpoint of adhesion, a modified polyphenylene ether is preferred. The modified polyphenylene ether has a substituent bonded to the polyphenylene ether chain or an end of the polyphenylene ether chain. The substituent is preferably a group having a reactive group, and more preferably a group having a vinyl group, a (meth)acryloyloxy group, or an epoxy group.

A hydrogen atom of a phenylene group in the polyphenylene ether chain may be substituted with an alkyl group, an alkenyl group, an alkynyl group, a formyl group, an alkylcarbonyl group, an alkenylcarbonyl group, or an alkynylcarbonyl group.

From the viewpoint of adhesion, dielectric properties, and the like, the weight average molecular weight of the thermosetting resin is preferably from 1,000 to 7,000, more preferably from 1,000 to 5,000, and still more preferably from 1,000 to 3,000.

From the viewpoint of adhesion of a prepreg obtained from the present composition 1, 2, 3, or 4 to a metal substrate layer of a wiring board or the like, the content of the thermosetting resin with respect to the total mass of each of the present compositions 1, 2, 3, and 4 is preferably from 10% to 40% by mass, more preferably from 15% to 35% by mass, and still more preferably from 20% to 30% by mass.

The present compositions 1 and 2 contain silica particles having a d50 of from 0.5 to 20.0 μm. From the viewpoint of achieving a high level of balance between the physical properties of the present compositions 1 and 2 themselves, such as dispersion stability, flowability, and suppression of uneven distribution of the silica particles, and the physical properties of the shaped materials formed from the present compositions 1 and 2, such as reduced water absorption, adhesion, and low dielectric tangent, the d50 of the silica particles in each of the present compositions 1 and 2 is preferably from 1.0 to 10.0 μm, and more preferably from more than 1.0 μm to 5.0 μm.

From the viewpoint of enhancing the above-described mechanism of action and facilitating the adjustment of the thixotropy ratio, the d50 of the silica particles in the present composition 3 is from 0.5 to 20.0 μm, preferably from 1.0 to 10.0 μm, and more preferably from more than 1.0 μm to 5.0 μm. In particular, when the d50 of the silica particles is 0.5 μm or more, the aggregation of the silica particles can be suppressed.

The d50 of the silica particles in the present composition 4 is from more than 1.0 μm to 5.0 μm. From the viewpoint of suppressing the aggregation of the silica particles, and from the viewpoint of excellent surface smoothness of a shaped material or the like, the d50 of the silica particles is preferably from 1.5 to 4.0 μm, and more preferably from 2.0 to 3.5 μm.

From the viewpoint of enhancing the interaction between the silica particles and the thermosetting resin while improving uniform dispersion in the present compositions 1, 2, and 4, the d10 of the silica particles is preferably from 0.5 to 5.0 μm, and more preferably from 1.0 to 3.0 μm.

From the viewpoint of enhancing the above-described mechanism of action and facilitating the adjustment of the thixotropy ratio, the d10 of the silica particles in the present composition 3 is preferably from 0.2 to 10.0 μm, more preferably from 0.5 to 5.0 μm, and still more preferably from 1.0 to 2.5 μm.

From the viewpoint of achieving a higher level of balance between the physical properties of the present composition 1 or 2 itself, such as dispersion stability and flowability, and the physical properties of the shaped material formed from the present composition 1 or 2, such as adhesion and low dielectric tangent, the specific surface area of the silica particles in each of the present compositions 1 and 2 is preferably from 0.3 to 3.0 m²/g, and more preferably from 0.8 to 2.0 m²/g.

From the viewpoint of further suppressing the aggregation of the silica particles and further stabilizing the present composition 3, the specific surface area of the silica particles in the present composition 3 is preferably from 0.1 to 3.5 m²/g, more preferably from 0.3 to 3.0 m²/g, and still more preferably from 0.8 to 2.0 m²/g.

From the viewpoint of the above-described mechanism of action and, in particular, the suppression of aggregation of the silica particles, the specific surface area of the silica particles in the present composition 4 is preferably from 0.1 to 5.0 m²/g, more preferably from 0.2 to 3.5 m²/g, still more preferably from 0.3 to 3.0 m²/g, particularly preferably from 0.6 to 2.4 m²/g, and most preferably from 0.8 to 2.0 m²/g. In this case, in particular, the wettability of the silica particles is improved, and the above-described mechanism of action tends to be significantly exhibited.

The ratio of the d50 to the d10 (d50/d10) of the silica particles in each of the present compositions 1, 2, and 4 is preferably from more than 1.0 to 5.0, more preferably from 1.3 to 4.0, and still more preferably from 1.5 to 3.0, from the viewpoint of improving the uniform dispersion of the silica particles in the present compositions 1, 2, and 4 while enhancing the interaction between the silica particles and the thermosetting resin.

The present composition 3 contains silica particles having a d50/d10 of from more than 1.0 to 5.0. From the viewpoint of enhancing the above-described mechanism of action and facilitating the adjustment of the thixotropy ratio, the d50/d10 is preferably from 1.1 to 4.0, more preferably from 1.2 to 2.4, and still more preferably from 1.3 to 2.2.

From the viewpoint of reducing the water absorption rate of the present compositions 1, 2, 3, and 4 and the cured products thereof, and the viewpoint of suppressing aggregation of the silica particles, the product A of the specific surface area of the silica particles and the d50 of the silica particles is preferably from 2.7 to 5.0 μm·m²/g, and more preferably from 2.9 to 4.5 μm·m²/g.

The particle size distribution of the silica particles contained in the present composition 1, 2, 3, or 4 is preferably unimodal. The fact that the particle size distribution of the silica particles is unimodal can be confirmed by the fact that the particle size distribution measured by the above-described laser diffraction/scattering method has a single peak.

The CV value of the particle diameter of the silica particles in each of the present compositions 1, 2, and 3 is preferably from 30% to 80%. From the viewpoint of suppressing aggregation of the silica particles, excellent surface smoothness of the shaped material and the like, the CV value is more preferably from 30% to 70%, still more preferably from 30% to 60%, and particularly preferably from 35% to 55%.

The CV value of the particle diameter of the silica particles in the present composition 4 is from 30% to 80%. From the viewpoint of the above-described mechanism of action, in particular, suppressing the aggregation of the silica particles, and from the viewpoint of excellent surface smoothness of a shaped material and the like, the CV value is preferably from 30% to 70%, more preferably from 30% to 60%, and still more preferably from 35% to 55%.

For the silica particles in the present compositions 1, 2, and 3, the proportion of particles having a particle diameter of 30 μm or more is preferably 500 ppm by number or less. In particular, from the viewpoint of excellent surface smoothness of a shaped material, the proportion is more preferably 300 ppm by number or less, still more preferably 200 ppm by number or less, and particularly preferably 100 ppm by number or less.

In the silica particles in composition 4, the proportion of particles having a particle diameter of 10 μm or more is 500 ppm by number or less. From the viewpoint of the above-described mechanism of action and, in particular, excellent surface smoothness of a shaped material, the proportion is preferably 300 ppm by number or less, more preferably 200 ppm by number or less, and still more preferably 100 ppm by number or less. The proportion of particles is preferably 0 ppm by number or more.

In the present composition 1, 2, 3, or 4, the shape of each silica particle of the silica particles is preferably spherical, from the viewpoint of achieving a high level of balance between the physical properties of the present composition 1, 2, 3, or 4 itself, such as dispersion stability and flowability, and the physical properties of a shaped material, such as a prepreg, formed from the present composition 1, 2, 3, or 4, such as high toughness, adhesion to a metal substrate layer, and low dielectric tangent. From the same viewpoint, the sphericity of the spherical silica particles is preferably 0.75 or more, more preferably 0.90 or more, still more preferably 0.93 or more, and particularly preferably 1.00. Further, from the same viewpoint, the silica particles are preferably non-porous particles.

From the viewpoint of reducing transmission loss in a circuit when using the metal substrate with a resin as a printed wiring board, the dielectric tangent of the silica particles is preferably 0.0020 or less, more preferably 0.0010 or less, and still more preferably 0.0008 or less, at a frequency of 1 GHz.

From the same viewpoint, the dielectric constant of the silica particles is preferably 5.0 or less, more preferably 4.5 or less, and still more preferably 4.1 or less, at a frequency of 1 GHz.

Each silica particle may be treated with a silane coupling agent. By treating the surface of the silica particles with a silane coupling agent, the amount of remaining silanol groups on the surface is reduced, the surface is hydrophobized, and moisture adsorption is suppressed, whereby the dielectric loss is improved. It also enhances the affinity with the thermosetting resin, and improves dispersion and strength after resin film formation.

Examples of the silane coupling agent include an aminosilane-based coupling agent, an epoxysilane-based coupling agent, a mercaptosilane-based coupling agent, a silane-based coupling agents, and an organosilazane compound. One type of silane coupling agent may be used singly, or two or more types thereof may be used in combination.

The amount of the silane coupling agent attached is preferably from 0.01 to 5 parts by mass, and more preferably 0.10 to 2 parts by mass, with respect to 100 parts by mass of the silica particles.

The fact that the surface of the silica particles has been treated with a silane coupling agent can be confirmed by detecting a peak of a substituent of the silane coupling agent by IR. The amount of the silane coupling agent attached can be measured based on the amount of carbon.

From the viewpoint of enhancing the interaction between the silica particles and the thermosetting resin thereby improving the toughness of a shaped material, the individual silica particles do not need to be surface-treated with a silane coupling agent or the like.

The silica particles contain preferably from 30 to 1500 ppm by mass, more preferably from 100 to 1000 ppm by mass, and still more preferably from 100 to 500 ppm by mass, of titanium (Ti). Ti is a component that is optionally included in the production of the silica particles. During the production of the silica particles, generation of fine powder due to cracking of the silica particles increases the specific surface area of the particles. By adding Ti during the production of the silica particles, the particles can be easily compacted by heat during firing, and the cracking of the particles can be suppressed. As a result, the generation of fine powder can be suppressed, and the amount of particles attached to the surface of the base particles of the silica particles can be reduced, making it easier to adjust the specific surface area of the silica particles. By including 30 ppm by mass or more of Ti, the silica particles are easily thermally compacted during the firing, and the generation of fine powder due to cracking can be suppressed. When the Ti content is 1,500 ppm by mass or less, in addition to obtaining the foregoing effect, increase in the amount of silanol groups can be suppressed, thereby lowering the dielectric tangent.

The silica particles may contain impurity elements other than titanium (Ti) as long as the effects of the present disclosure are not impaired. Examples of the impurity elements other than Ti include Na, K, Mg, Ca, Al, and Fe. The total content of alkali metals and alkaline earth metals among the impurity elements is preferably 2000 ppm by mass or less, more preferably 1000 ppm by mass or less, and still more preferably 200 ppm by mass or less.

The silica particles are preferably silica particles produced by a wet method. The wet method refers to a technique that involves a process of gelling a liquid silica source to obtain a raw material for the silica particles. By using the wet method, the shape of the silica particles tends to be easily adjusted, and in particular, spherical silica particles tend to be easily prepared. Therefore, it is not necessary to adjust the particle shape by crushing or the like, and as a result, particles with a small specific surface area tend to be easily obtained. Further, in the wet method, particles that are significantly smaller than the average particle diameter are less likely to be generated, and the specific surface area after firing tends to be small. In addition, in the wet method, the amount of impurity elements, such as titanium, can be adjusted by adjusting the impurities in the silica source, and further, the above-described impurity elements can be uniformly dispersed in the particles.

Examples of the wet method include a spray method and an emulsion-gelation method. In the emulsion-gelation method, for example, a continuous phase and a dispersed phase containing a silica precursor are emulsified, and the resulting emulsion is gelled to obtain a spherical silica precursor. A preferred emulsification method is a method in which a dispersed phase containing a silica precursor is added to a continuous phase through a microporous portion or a porous membrane, thereby preparing an emulsion. This allows the production of an emulsion having a uniform droplet size, resulting in spherical silica particles having a uniform particle diameter. Examples of such an emulsification method include a micromixer method and a membrane emulsification method. For example, the micromixer method is disclosed in WO2013/062105.

The silica particles can be obtained by heat-treating the silica precursor. The heat treatment has an effect of sintering the spherical silica precursor to densify the shell, as well as reducing the amount of silanol groups on the surface to lower the dielectric tangent. The temperature of the heat treatment is preferably 700° C. or more. From the viewpoint of suppressing the aggregation of the particles, the temperature of the heat treatment is preferably 1600° C. or less. Further, the obtained silica particles may be surface-treated with a silane coupling agent.

From the viewpoint of suppressing uneven distribution of the silica particles, reducing water absorption, low dielectric tangent, adhesion, and the like, the amount of the silica particles with respect to 100 parts by mass of the thermosetting resin in the present composition 1, 2, 3, or 4 is preferably 10 parts by mass or more, more preferably 50 parts by mass or more, still more preferably 70 parts by mass or more, particularly preferably 90 parts by mass or more, or may be 100 parts by mass or more. The amount is preferably 600 parts by mass or less, more preferably 400 parts by mass or less, still more preferably 300 parts by mass or less, and particularly preferably 250 parts by mass or less. In particular, when a high filling rate of the silica particles is desired, the amount of the silica particles is preferably 80 parts by mass or more, more preferably 90 parts by mass or more, and particularly preferably 100 parts by mass or more. In this case, the amount of the silica particles is preferably 600 parts by mass or less, and more preferably 300 parts by mass or less. Even when the amount of the silica particles is large, owing to the above-described mechanism of action, a shaped material having a particularly low water absorption rate can be obtained from the present composition 1, 2, 3, or 4.

The silica particles in the present composition 1, 2, 3, or 4 are in a state in which the particles are sufficiently wetted and uniformly dispersed, and in which the particles easily interact with the thermosetting resin. Therefore, even in the present composition in which a large amount of silica particles are contained with respect to the thermosetting resin, both components tend to be easily stabilized, and a shaped material having excellent adhesion to a metal substrate layer can be formed.

The present composition 1, 2, 3, or 4 may contain one or more kinds of curing agents. A curing agent is an agent that initiates a curing reaction of a thermosetting resin by the action of heat. Specific examples thereof include α,α′-bis(t-butylperoxy-m-isopropyl)benzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile. The amount of the curing agent with respect to 100 parts by mass of the thermosetting resin is preferably from 0.1 to 5 parts by mass.

The present composition 1, 2, 3, or 4 may contain one or more kinds of curing accelerators. Examples of the curing accelerator include: a trialkenyl isocyanurate compound, such as triallyl isocyanurate; a polyfunctional acrylic compound having two or more acryloyl or methacryloyl groups in the molecule; a polyfunctional vinyl compound having two or more vinyl groups in the molecule; and a vinylbenzyl compound having a vinylbenzyl group in the molecule, such as styrene. The amount of the curing accelerator with respect to 100 parts by mass of the thermosetting resin is preferably from 10 to 100 parts by mass.

The present compositions 1 and 4 may contain one or more kinds of solvents. From the viewpoint of reducing the water absorption rate of the present composition 1 and 4 and a cured product thereof or the like, the surface tension of the solvent is preferably 45 mN/m or less, more preferably 40 mN/m or less, still more preferably 35 mN/m or less, and particularly preferably 30 mN/m or less. The lower limit of the surface tension is not particularly limited, and may be 5 mN/m or more.

The present composition 2 contains a solvent having a surface tension of 45 mN/m or less. From the viewpoint of suppressing uneven distribution of the silica particles, reducing water absorption, and the like, the surface tension of the solvent is preferably 40 mN/m or less, more preferably 35 mN/m or less, and still more preferably 30 mN/m or less. The lower limit of the surface tension is not particularly limited, and may be 0.05 mN/cm or more.

The present composition 3 contains a solvent. From the viewpoint of suppressing uneven distribution of the silica particles, reducing water absorption, and the like, the surface tension of the solvent contained in the present composition 3 is preferably 45 mN/m or less, more preferably 40 mN/m or less, and still more preferably 35 mN/m or less. The lower limit of the surface tension is not particularly limited, and may be, for example, 5 mN/m.

From the viewpoint of improving the flowability and ease of handling of the composition at the time of thermally curing the present composition 1, 2 or 4 to form a shaped material such as a prepreg, the boiling point of the solvent in each of the present compositions 1, 2, and 4 is preferably 75° C. or more, more preferably 80° C. or more, and still more preferably 90° C. or more. The upper limit of the boiling point is not particularly limited, and may be 200° C. or less.

The boiling point of the solvent in the present composition 3 is 75° C. or more. From the viewpoint of enhancing the above-described mechanism of action, the boiling point is preferably 80° C. or more, and more preferably 90° C. or more. The upper limit of the boiling point is not particularly limited, and may be 200° C. or less.

From the viewpoint of ease of handling at the time of thermally curing the present composition 1, 2, or 4 to form a shaped material such as a prepreg, and suppression of aggregation of the silica particles associated with evaporation of the solvent upon heating, the evaporation rate of the solvent in each of the present compositions 1, 2 and 4 is preferably from 0.3 to 3.0, and more preferably from 0.4 to 2.0.

The evaporation rate of the solvent in the present composition 3 is from 0.3 to 4.0. From the viewpoint of ease of handling at the time of thermally curing the present composition 3 to form a shaped material such as a prepreg, and suppression of aggregation of the silica particles associated with evaporation of the solvent upon heating, the evaporation rate is preferably from 0.4 to 2.0.

Examples of the solvent in the present composition 1, 2, or 4 include acetone, methanol, ethanol, butanol, 2-propanol, 2-methoxyethanol, 2-ethoxyethanol, toluene, xylene, methyl ethyl ketone, N,N-dimethylformamide, methyl isobutyl ketone, N-methyl-2-pyrrolidone, n-hexane, and cyclohexane. From the viewpoint of adhesion of a shaped material such as a prepreg to a metal substrate layer or the like, the solvent preferably includes at least one selected from the group consisting of toluene (110° C., 28 mN/cm, 0.58), cyclohexanone (156° C., 35 mN/cm, 0.32), methyl ethyl ketone (80° C., 24.6 mN/cm, 3.7), and N-methyl-2-pyrrolidone (202° C., 42 mN/m, from 0.3 to 4.0). Here, the numbers in the parentheses indicate the boiling point, the surface tension, and the evaporation rate in this order.

Examples of the solvent in the present composition 3 include: a hydrocarbon, such as toluene (111° C., 2.0), methylcyclohexane (101° C., 3.20), normal heptane (98° C., 3.62), or m-xylene (139° C., 0.76); an alcohol, such as ethanol (78° C., 1.54), isopropyl alcohol (82° C., 1.5), 1-propyl alcohol (97° C., 0.94), isobutyl alcohol (107° C., 0.64), 1-butanol (118° C., 0.47), or 2-butanol (100° C., 0.89); an acetate ester, such as propyl acetate (102° C., 2.14), isobutyl acetate (118° C., 1.45), or butyl acetate (126° C., standard value); a ketone, such as methyl ethyl ketone (80° C., 3.7), methyl isobutyl ketone (116° C., 1.6), or cyclohexanone (156° C., 0.32); a cellosolve, such as ethylene glycol monomethyl ether (125° C., 0.53) or ethylene glycol monoethyl ether (136° C., 0.38); a glycol ether, such as 1-methoxy-2-propanol (120° C., 0.71), 1-methoxypropyl-2-acetate (146° C., 0.44), 1-ethoxy-2-propanol (132° C., 0.34), or 3-ethoxyethyl propionate (170° C., 0.34); a chlorinated hydrocarbon, such as trichloroethylene (87° C., 3.22) or tetrachloroethylene (121° C., 1.29); and N-methyl-2-pyrrolidone (202° C., from 0.3 to 4.0). Here, the numbers in the parentheses indicate the boiling point and evaporation rate in this order.

Among these, from the viewpoint of adhesion or the like, the solvent preferably contains at least one selected from the group consisting of toluene, cyclohexanone, methyl ethyl ketone, and N-methyl-2-pyrrolidone.

The present composition 3 contains a solvent having a boiling point of 75° C. or more and an evaporation rate of from 0.3 to 4.0, and may contain other solvent(s) as long as they do not contradict the object of the present disclosure.

Examples of said other solvent include: a hydrocarbon, such as hexane, cyclohexane, or benzene; an alcohol, such as methanol; an acetate ester, such as methyl acetate or ethyl acetate; a ketone, such as acetone, diisobutyl ketone, 4-hydroxy-4-methyl-2-pentanone, or isophorone; a cellosolve, such as ethylene glycol mono-n-butyl ether, ethylene glycol mono-t-butyl ether, or 2-ethoxyethyl acetate; a glycol ether, such as 3-methoxy-3-methylbutanol, 3-methoxy-3-methylbutyl acetate, propylene glycol monopropyl ether, 3-methoxybutyl acetate, propylene glycol monomethyl ether propionate, diethylene glycol monobutyl ether, or triethylene glycol monobutyl ether; an ether, such as tetrahydrofuran or diethyl ether; and chlorinated hydrocarbons, such as dichloromethane, 1,1,1-trichloroethane, or 1,1-dichloro-1-fluoroethane.

The proportion of the solvent having a boiling point of 75° C. or more and an evaporation rate of from 0.3 to 4.0 with respect to the solvent contained in the present composition 3 is preferably 70% by volume or more, more preferably 80% by volume or more, still more preferably 90% by volume or more, and particularly preferably 100% by volume. In other words, it is particularly preferable to use only a solvent having a boiling point of 75° C. or more and an evaporation rate of from 0.3 to 4.0.

The content of the solvent with respect to the total mass of the present compositions 1, 2, 3, or 4 is not particularly limited, and may be from 10% to 60% by mass, from 20% to 50% by mass, or from 30% to 40% by mass.

The amount of the silica particles with respect to 100 parts by mass of the solvent in the present composition 1, 2, 3, or 4 is preferably from 50 to 550 parts by mass, or may be from 100 to 500 parts by mass, from 125 to 400 parts by mass, or from 150 to 300 parts by mass. Even when the amount of the silica particles with respect to the amount of the solvent is large, the silica particles are highly wetted owing to the above-described mechanism of action, and a favorable balance between uniform dispersion and viscosity of the composition tends to be achieved. Therefore, even when the amount of the silica particles is large, the viscosity of the composition tends not to increase.

The present composition 1, 2, 3, or 4 may contain one or more kinds of plasticizers. Examples of the plasticizer include a butadiene-styrene copolymer. The amount of the plasticizer with respect to 100 parts by mass of the thermosetting resin is preferably from 10 to 50 parts by mass, and more preferably from 20 to 40 parts by mass.

The present composition 1, 2, 3, or 4 may further contain other component(s), in addition to the above-described components, such as a surfactant, a thixotropic agent, a pH adjuster, a pH buffer, a viscosity regulator, a defoamer, a silane coupling agent, a dehydrating agent, a weathering agent, an antioxidant, a heat stabilizer, a lubricant, an antistatic agent, a brightener, a colorant, a conductive material, a release agent, a surface treatment agent, a flame retardant, or various organic or inorganic fillers, as long as the effects of the composition are not impaired.

A prepreg 1 according to the present disclosure includes: the present composition 1 or a semi-cured product thereof; and a fibrous substrate.

A prepreg 2 according to the present disclosure includes: the present composition 2 or a semi-cured product thereof; and a fibrous substrate.

A prepreg 3 according to the present disclosure includes: the present composition 3 or a semi-cured product thereof; and a fibrous substrate.

A prepreg 4 according to the present disclosure includes: the present composition 4 or a semi-cured product thereof; and a fibrous substrate.

The fibrous substrate preferably contains a glass component. Examples of the fibrous substrate include glass cloth, aramid cloth, polyester cloth, glass nonwoven fabric, aramid nonwoven fabric, polyester nonwoven fabric, and pulp paper. The thickness of the fibrous substrate is not particularly limited, and may be from 3 to 10 μm. Since the present compositions 1, 2, 3, and 4 are described above, the description thereof will be omitted here.

The prepreg 1, 2, 3, or 4 according to the present disclosure can be produced by coating or impregnating the fibrous substrate with the corresponding present composition 1, 2, 3, or 4. After the coating or impregnation with the present composition 1, 2, 3, or 4, the liquid composition may be heated to be semi-cured.

The metal substrate with a resin 1 according to the present disclosure includes: the present composition 1 or a semi-cured product thereof or the above-described prepreg 1; and a metal substrate layer. The metal substrate layer may be provided at the surface of one side or both sides of the present composition 1 or the semi-cured product thereof or the above-described prepreg 1.

The metal substrate with a resin 2 according to the present disclosure includes: the present composition 2 or a semi-cured product thereof or the above-described prepreg 2; and a metal substrate. The metal substrate layer may be provided at one side or both sides of the present composition 2 or a semi-cured product or the above-described prepreg 2.

The metal substrate with a resin 3 according to the present disclosure includes: the present composition 3 or a semi-cured product thereof or the above-described prepreg 3; and a metal substrate. The metal substrate layer may be provided at one side or both sides of the present composition 3 or a semi-cured product or the above-described prepreg 3.

The metal substrate with a resin 4 according to the present disclosure includes: the present composition 4 or a semi-cured product thereof or the above-described prepreg 4; and a metal substrate layer. The metal substrate layer may be provided at one side or both sides of the present composition 4 or a semi-cured product or the above-described prepreg 4.

The type of the metal substrate layer is not particularly limited, and examples of the metal constituting the metal substrate layer include copper, a copper alloy, stainless steel, nickel, a nickel alloy (including alloy 42), aluminum, an aluminum alloy, titanium, and a titanium alloy. The metal substrate layer is preferably a metal foil, and more preferably a copper foil, such as a rolled copper foil or an electrolytic copper foil. The surface of the metal foil may be subjected to an anti-rust treatment (such as an oxide film of chromate or the like) or a roughening treatment. As the metal foil, a metal foil with a carrier, that has a carrier copper foil (thickness: from 10 to 35 μm) and an ultra-thin copper foil (thickness: from 2 to 5 μm) layered on the surface of the carrier copper foil via a release layer, may be used. The surface of the metal substrate layer may be treated with a silane coupling agent. In this case, the entire surface of the metal substrate layer may be treated with the silane coupling agent, or only a part of the surface of the metal substrate layer may be treated with the silane coupling agent. Those mentioned above may be used as the silane coupling agent.

The thickness of the metal substrate layer is preferably from 1 to 40 μm, and more preferably from 2 to 15 μm. From the viewpoint of reducing the transmission loss when the metal substrate with a resin is used as a printed wiring board, the maximum height roughness (Rz) of the metal substrate layer (e.g., copper foil) is preferably 2 μm or less, and more preferably 1.2 μm or less. It is preferable that the Rz of the surface of the metal substrate layer (e.g., copper foil) facing the liquid composition, the semi-cured product, or the prepreg is within the foregoing ranges. When the metal substrate with a resin is used as a printed wiring board, the transmission loss can generally be reduced, whereas the adhesion between the metal substrate layer and the prepreg or the like generally tends to decrease. According to the prepreg 1, 2, 3, or 4 using the present composition 1, 2, 3, or 4 according to the present disclosure, the decrease in adhesion described above can be suppressed, and the transmission loss can be reduced.

In one embodiment, the metal substrate with a resin 1, 2, 3, or 4 according to the present disclosure can be produced by coating the surface of the metal substrate layer with the corresponding present composition 1, 2, 3, or 4. After the coating of the present composition 1, 2, 3, or 4, the liquid composition may be heated to be semi-cured.

In another embodiment, the metal substrate with a resin 1, 2, 3, or 4 according to the present disclosure can be produced by layering the metal substrate layer and the corresponding prepreg 1, 2, 3, or 4. Examples of the method of layering the metal substrate layer and the prepreg 1, 2, 3, or 4 include a method of subjecting them to thermal compression bonding.

A wiring board 1 according to the present disclosure includes a cured product of the present composition 1 and a metal wiring.

A wiring board 2 according to the present disclosure includes a cured product of the present composition 2 and a metal wiring.

A wiring board 3 according to the present disclosure includes a cured product of the present composition 3 and a metal wiring.

A wiring board 4 according to the present disclosure includes a cured product of the present composition 4 and a metal wiring.

As the metal wiring, a metal wiring produced by, for example, etching the above-described metal substrate layer can be used.

The wiring board 1, 2, 3, or 4 according to the present disclosure can be produced, for example, by a method of etching the metal substrate layer of the above-described corresponding metal substrate with a resin 1, 2, 3, or 4, or a method of forming a pattern circuit on the surface of a cured product of the present composition 1, 2, 3, or 4 by electrolytic plating (semi-additive process (SAP process), modified semi-additive process (MSAP process), or the like).

In one embodiment, silica particles are used for adjusting the viscosity of a liquid composition containing a thermosetting resin, and have a d50 of from 0.5 to 20.0 μm and a specific surface area of from 0.1 to 3.5 m²/g.

In another embodiment, silica particles are used to be added to a liquid composition containing a thermosetting resin, and have a d50 of from 0.5 to 20 μm, the product of the specific surface area thereof and the d50 thereof being from 2.7 to 5.0 μm·m²/g.

In another embodiment, silica particles are used for adjusting a thixotropy of a liquid composition containing a thermosetting resin, and have a d50 of from 0.5 to 20.0 μm and a d50/d10 of from more than 1.0 to 5.0.

In another embodiment, silica particles are used to be mixed with a liquid composition containing a thermosetting resin thereby forming a prepreg, and in a particle size distribution obtained by a Coulter counter method, the proportion of particles having a particle diameter of 10 μm or more is 500 ppm by number or less, the coefficient of variation of particle diameter is from 0.30 to 0.80, and the d50 is from more than 1.0 μm to 5.0 μm.

The details of the d50, d10, specific surface area, product of the specific surface area and d50, d50/d10, CV value, proportion of particles having a particle diameter of 10 μm or more, particle size distribution, shape, sphericity, dielectric tangent, dielectric constant, surface treatment, elements that may be contained, manufacturing method, and the like, with regard to the silica particles are described above, and therefore, are omitted here.

### EXAMPLES

Hereinafter, embodiments of the present disclosure will be described in detail with reference to Examples. However, the embodiments of the present disclosure are not limited thereto.

### Method of Measuring d10 and d50 of Silica Particles

The d10 and d50 of the silica particles in Examples 11 to 19, 21 to 27, and 31 to 35 were measured by a laser diffraction/scattering method using a particle size distribution measuring device (MT3300EXII manufactured by MicrotracBEL Corp.). Specifically, the silica particles were dispersed in the device by irradiating them with ultrasonic waves three times for 60 seconds, and then the measurement was performed. The d10 and d50 were measured twice for 60 seconds each, and the average value was calculated. The aperture diameter was set to 20 μm.

The d50 of the silica particles in Examples 41 to 48 was measured by the Coulter counter method described later.

### Method of Measuring Specific Surface Area of Silica Particles

The following silica particles were dried at 230° C. under reduced pressure to remove the moisture completely, and were used as the samples. The specific surface areas of the samples were determined by the multipoint BET method using nitrogen gas by an automatic specific surface area/pore distribution measuring device, Tristar II, manufactured by Micromeritics Instrument Corporation.

### Methods of Measuring Viscosity and Thixotropy Ratio

The measurements were carried out using a rotational rheometer (Modular Rheometer Physica MCR-301 manufactured by Anton Paar).

The viscosity was measured at 25° C. for 30 seconds at a shear rate of 1 rpm, and the viscosity obtained at 30 seconds was regarded as the viscosity. The thixotropy ratio was calculated by dividing the viscosity measured at a rotation speed of 1 rpm by the viscosity measured at a rotation speed of 60 rpm.

### 1. Preparation of Components for Producing Liquid Composition

### [Thermosetting Resin]

Polyphenylene ether resin: Modified polyphenylene ether in which the terminal hydroxyl groups of polyphenylene ether are modified with methacryloyloxy groups (SABIC: Noryl SA9000; Mw: 1700; number of functional groups per molecule: 2)

### [Silica Particles]

Silica particles A: Silica particles obtained by filling an alumina crucible with 15 g of silica powder 1 (H-31 manufactured by AGC Si-Tech Co., Ltd.; d50: 3.5 μm) produced by a wet method as a spherical silica precursor, heat-treating the powder at a temperature of 1200° C. in an electric furnace for 1 hour, followed by cooling to 25° C. and then crushing in an agate mortar

Silica particles B: Silica particles obtained by filling an alumina crucible with 15 g of silica powder 2 (E-2C manufactured by SUZUKIYUSHI INDUSTRIAL CORPORATION; d50: 2.5 μm) produced by a wet method as a spherical silica precursor, heat-treating the powder at a temperature of 1200° C. in an electric furnace for 1 hour, followed by cooling to 25° C. and then crushing in an agate mortar

Silica particles C: Silica particles produced by the vaporized metal combustion (VMC) method (SC5500-SQ manufactured by Admatechs Co. Ltd)

Silica particles D: Silica particles produced by a dry method (SPH516 manufactured by Micron, Inc.)

Silica particles E: Silica particles produced by a wet method (H-201 manufactured by AGC Si-Tech Co., Ltd.; d50: 20.0 μm)

Silica particles F: Silica powder produced by a wet method (E-2C manufactured by SUZUKIYUSHI INDUSTRIAL CORPORATION; d50: 2.5 μm)

Silica particles G: Silica particles produced by the VMC method (SO-C1 manufactured by Admatechs Co. Ltd)

Silica particles 3C: Silica particles described in Example 1 of JP 2018-145037 A

Silica particles 4B: Silica particles prepared by classifying the silica particles A using a precision air classifier (Turbo Classifier TC-10 manufactured by NISSHIN ENGINEERING INC.) such that no particles of 10 μm or more are observed

Silica particles 4C: Silica particles prepared by pulverizing the silica particles A in a jet mill (Super Jet Mill SJ-100, manufactured by NISSHIN ENGINEERING INC.) at a pulverization pressure of 0.5 MPa

Silica particles 4D: Trade name “HIPRESICA (registered trademark)” manufactured by UBE EXSYMO CO., LTD.

Silica particles 4E: Trade name “SEAHOSTAR (registered trademark) KE-S S50” manufactured by NIPPON SHOKUBAI CO., LTD.

Silica particles 4F: Trade name “FB-5D” manufactured by Denka Company Limited

### [Solvent]

Toluene: Boiling point of 111° C., evaporation rate of 2.0

Diisobutyl ketone (DIBK): Boiling point of 168° C., evaporation rate of 0.2

Cyclohexanone: Boiling point of 156° C., evaporation rate of 0.32

### [Plasticizer]

Butadiene-styrene random copolymer (Ricon 100, Cray Valley)

### [Curing Accelerator]

Triallyl isocyanurate (TAIC, Mitsubishi Chemical Group Corporation)

### [Curing Agent]

α,α′-Di(t-butylperoxy)diisopropylbenzene (PERBUTYL (registered trademark) P, NOF CORPORATION)

### 2. Production of Liquid Composition, Prepreg, and Metal Substrate With Resin

### Example 11

59 parts by mass of a polyphenylene ether resin, 16 parts by mass of a butadiene-styrene random copolymer, 25 parts by mass of triallyl isocyanurate, 1 part by mass of α,α′-di(t-butylperoxy)diisopropylbenzene, 55 parts by mass of silica particles A, and 80 parts by mass of toluene were placed in a polyethylene bottle. Alumina balls having a diameter (Φ) of 20 mm were added thereto and mixed at 30 rpm for 12 hours, and the alumina balls were then removed to obtain a liquid composition. The liquid composition contains 68.75 parts by mass of the silica particles A with respect to 100 parts by mass of toluene, and 93 parts by mass of the silica particles A with respect to 100 parts by mass of the polyphenylene ether resin.

The liquid composition was applied to a glass cloth of IPC spec 2116 by impregnation and then heated and dried at 160° C. for 4 minutes to obtain a prepreg.

18-μm thick copper foils with a carrier (copper foil thickness: 3 μm; maximum height roughness Rz: 2 μm; MT18E manufactured by MITSUI MINING & SMELTING CO., LTD.) were layered on both sides of the prepreg, and the laminate was heat-treated at 230° C. and a pressure of 30 kg/cm2 for 120 minutes to obtain a metal substrate with a resin.

### Examples 12 to 17

Liquid compositions, prepregs, and metal substrates with a resin were produced in the same manner as in Example 11, except that the silica particles A were replaced with the silica particles shown in Table 1.

### Examples 18 to 19

A liquid composition of Example 18 containing 137.5 parts by mass of the silica particles A with respect to 100 parts by mass of toluene was obtained in the same manner as in Example 11 except that the amount of toluene was 40 parts by mass. A liquid composition of Example 19 containing 137.5 parts by mass of the silica particles C with respect to 100 parts by mass of toluene was obtained in the same manner as in Example 13 except that the amount of toluene was 40 parts by mass. Using the obtained liquid compositions, prepregs and metal substrates with a resin were produced in the same manner as in Example 11.

### [Measurement of Peel Strength]

In accordance with IPC-TM650-2.4.8, the peel strength between the prepreg and the copper foil with a carrier was measured using a TENSILON universal testing machine (RTC-1250A manufactured by A&D Company, Limited). The measurement results are summarized in Table 1.

Here, Examples 11 to 13, 18, and 19 are working examples, and Examples 14 to 17 are comparative examples.

TABLE 1

| | Silica particles | | | Liquid | Prepreg |
|---|---|---|---|---|---|
| | | | Specific | composition | Peel |
| | | d50 | surface area | Viscosity | strength |
| | Type | (μm) | (m²/g) | (mPa · s) | (lb/in) |
| Example 11 | A | 3.0 | 1.0 | 200 | 3.5 |
| Example 12 | B | 2.0 | 2.2 | 250 | 3.0 |
| Example 13 | E | 20.0 | 0.1 | 160 | 2.4 |
| Example 14 | C | 1.5 | 5.0 | 4500 | 1.0 |
| Example 15 | F | 2.2 | 50.0 | 10500 | 1.2 |
| Example 16 | D | 0.64 | 12.7 | 12000 | 0.5 |
| Example 17 | G | 0.4 | 15.0 | 18000 | 0.2 |
| Example 18 | A | 3.0 | 1.0 | 400 | 3.2 |
| Example 19 | E | 20.0 | 0.1 | 1020 | 1.6 |

Table 1 shows that prepreg 1 using the present composition 1 has excellent adhesion to the metal substrate layer.

### Example 21

A liquid composition, a prepreg, and a metal substrate with a resin were produced in the same manner as in Example 11, except that toluene was replaced with cyclohexanone.

### Examples 22 to 25

Liquid compositions, prepregs, and metal substrates with a resin were produced in the same manner as in Example 21, except that at least one of the solvent or the silica particles A was replaced with those shown in Table 2.

### Examples 26 to 27

A liquid composition of Example 26 containing 138 parts by mass of the silica particles A with respect to 100 parts by mass of the polyphenylene ether resin was obtained in the same manner as in Example 22 except that the amount of the polyphenylene ether resin was 40 parts by mass. A liquid composition of Example 27 containing 138 parts by mass of the silica particles B with respect to 100 parts by mass of the polyphenylene ether resin was obtained in the same manner as in Example 23 except that the amount of the polyphenylene ether resin was 40 parts by mass. Using the obtained liquid compositions, prepregs and metal substrates with a resin were produced in the same manner as in Example 21.

### [Confirmation of Presence or Absence of Silica Particle Aggregation]

The prepregs produced in Examples 21 to 27 were visually observed to confirm the presence or absence of silica particle aggregation. Those in which no silica particle aggregation was observed were rated A, those in which a small amount of silica particle aggregation was observed were rated B, and those in which a large amount of silica particle aggregation was observed were rated C. The results are summarized in Table 2.

### [Measurement of Water Absorption Rate]

The water absorption rates of the metal substrates with a resin were measured according to IPC TM-650 2.6.2.1. The water absorption rate of Example 24 was set to 1.00, and the water absorption rates of the other Examples were calculated as relative values. The results are summarized in Table 2.

Here, Examples 21 to 23, 26, and 27 are working examples, and Examples 24 and 25 are comparative examples.

TABLE 2

| | Silica particles | | | | | | Presence or | |
|---|---|---|---|---|---|---|---|---|
| | | | Specific | d50 × | Solvent | | Absence | |
| | | | surface | Specific | | Surface | of Silica | Water |
| | | d50 | area | surface area | | tension | Particle | absorption |
| | Type | (μm) | (m²/g) | (μm · m²/g) | Type | (mN/m) | Aggregation | rate |
| Example 21 | A | 3.0 | 1.0 | 3.0 | Cyclohexanone | 35 | B | 0.25 |
| Example 22 | A | 3.0 | 1.0 | 3.0 | Toluene | 28 | A | 0.15 |
| Example 23 | B | 2.0 | 2.2 | 4.4 | Toluene | 28 | A | 0.25 |
| Example 24 | C | 1.5 | 5.0 | 7.5 | Toluene | 28 | C | 1.00 |
| Example 25 | D | 0.64 | 12.7 | 8.1 | Toluene | 28 | C | 0.50 |
| Example 26 | A | 3.0 | 1.0 | 3.0 | Toluene | 28 | A | 0.16 |
| Example 27 | B | 2.0 | 2.2 | 4.4 | Toluene | 28 | A | 0.38 |

Table 2 shows that, in prepreg 2 using the present composition 2, the uneven distribution of the silica particles is suppressed, resulting in a reduced absorption rate.

### Example 31

A liquid composition, a prepreg, and a metal substrate with a resin were produced in the same manner as in Example 11.

### Examples 32 to 35

Liquid compositions, prepregs, and metal substrates with a resin were produced in the same manner as in Example 31, except that the silica particles and solvents used were as shown in Table 3.

### [Standard Deviation of Dielectric Constant]

The dielectric constant was measured using a perturbation resonator method with a “Vector Network Analyzer E5063A” manufactured by KEYCOM Corporation. The dielectric constant was measured at the center in the short side direction of each of the obtained prepregs at the points of 1L/4, 2L/4, and 3L/4 in the long side direction L, and the standard deviation of the values at the three points was calculated. The measurement results are summarized in Table 3.

Here, Examples 31 and 32 are working examples, and Examples 33 to 35 are comparative examples.

TABLE 3

| | | | | | | | | | Prepreg |
|---|---|---|---|---|---|---|---|---|---|
| | Silica particles | | | | | | | Liquid | Dielectric |
| | | | | | Specific | Solvent | | composition | constant |
| | | d50 | d10 | d50/ | surface area | | Evaporation | Thixotropy | standard |
| | Type | (μm) | (μm) | d10 | (m²/g) | Type | rate | ratio | deviation |
| Example 31 | A | 3.0 | 1.6 | 1.9 | 1.0 | Toluene | 2.0 | 1.5 | 0.08 |
| Example 32 | B | 2.0 | 1.2 | 1.7 | 2.2 | Toluene | 2.0 | 1.8 | 0.10 |
| Example 33 | 3C | 24.0 | 2.0 | 12.0 | 1.2 | DIBK | 0.20 | 5.0 | 0.16 |
| Example 34 | G | 0.4 | 0.1 | 4.0 | 15.0 | DIBK | 0.20 | 13.0 | 0.48 |
| Example 35 | G | 0.4 | 0.1 | 4.0 | 15.0 | Toluene | 2.0 | 10.8 | 0.31 |

Table 3 shows that, in the prepreg 3 using the present composition 3, the standard deviation of the dielectric constant is low, indicating that the aggregation of the silica particles is suppressed. It is considered that this allows high-filling of the silica particles, allowing the silica particles to exhibit their properties favorably.

### Example 41

A liquid composition and a prepreg were produced in the same manner as in Example 11, except that the amount of the silica particles A was changed from 55 parts by mass to 220 parts by mass.

Three sheets of the prepreg were stacked, and 18-μm thick ultra-thin copper foils with a carrier (copper foil thickness: 3 μm; Rz: 2 μm; MT18E manufactured by MITSUI MINING & SMELTING CO., LTD.) were layered on top and bottom, and the laminate was heat-treated at 230° C. and a pressure of 60 kg/cm2 for 120 minutes to obtain a metal substrate with a resin.

### Examples 42 to 46

Liquid compositions, prepregs, and metal substrates with a resin were produced in the same manner as in Example 41, except that the silica particles A were replaced with the silica particles shown in Table 4.

### Examples 47 to 48

A liquid composition of Example 47 containing 550 parts by mass of silica particles A with respect to 100 parts by mass of toluene and 550 parts by mass of silica particles A with respect to 100 parts by mass of polyphenylene ether was obtained in the same manner as in Example 41 except that the amount of the toluene was 40 parts by mass and the amount of the polyphenylene ether resin was 40 parts by mass. A liquid composition of Example 48 containing 550 parts by mass of silica particles 4C with respect to 100 parts by mass of toluene and 550 parts by mass of silica particles 4C with respect to 100 parts by mass of the polyphenylene ether resin was obtained in the same manner as in Example 43 except that the amount of the toluene was 40 parts by mass and the amount of the polyphenylene ether resin was 40 parts by mass. Using the obtained liquid compositions, prepregs and metal substrates with a resin were produced in the same manner as in Example 41.

In each Example, the d50 of the silica particles, the coefficient of variation of the particle diameter, and the proportion of particles having a particle diameter of 10 μm or more were measured by the Coulter counter method using the above-described instrument. The aperture diameter was set to 20 μm.

### [Measurement of Rzjis of Metal Substrate With Resin]

The Rzjis value of the back surface (shine surface) of a copper foil of each of the metal substrates with a resin was measured using a contact surface roughness meter (“SURFCOM NEX001” manufactured by TOKYO SEIMITSU CO., LTD.) to estimate the Rzjis value of the front surface (matte surface) of the copper foil to which the prepreg was thermally bonded. A measuring probe having a tip radius of 2 μm and a cone (taper angle: 60 degrees) was used. The cutoff values were Ac of 0.8 mm and As of 2.5 μm, the reference length of the roughness curve was 0.8 mm, and the evaluation length of the roughness curve was 4.0 mm. Here, Examples 41 to 43, 47, and 48 are working examples, and Examples 44 to 46 are comparative examples.

TABLE 4

| | Silica particles | | | | | |
|---|---|---|---|---|---|---|
| | | | | | Proportion of | |
| | | | | Coefficient of | particles with | Metal substrate |
| | | | Specific | variation of | particle diameter of | with a resin |
| | | d50 | surface area | particles | 10 μm or more | Rzjis |
| | Type | (μm) | (m²/g) | (%) | (ppm by number) | (μm) |
| Example 41 | A | 3.0 | 1.0 | 40 | 350 | 3 |
| Example 42 | 4B | 2.8 | 1.2 | 35 | 0 | 1 |
| Example 43 | 4C | 2.6 | 1.1 | 55 | 0 | 2 |
| Example 44 | 4D | 1.0 | 12.0 | 2 | 0 | 15 |
| Example 45 | 4E | 0.5 | 6.0 | 3 | 0 | 28 |
| Example 46 | 4F | 5.2 | 1.8 | 80 | 600 | 12 |
| Example 47 | A | 3.0 | 1.0 | 40 | 350 | 9 |
| Example 48 | 4C | 2.6 | 1.1 | 55 | 0 | 3 |

Table 4 shows that, in Examples 41 to 43 and 47 to 48, in which the present composition 4 was used, the Rzjis of the surface of the shaped material was low, and that, therefore, a shaped material having excellent surface smoothness can be obtained.

The disclosures of Japanese Patent Application No. 2022-065910, filed on Apr. 12, 2022, Japanese Patent Application No. 2022-065911, filed on Apr. 12, 2022, Japanese Patent Application No. 2022-065665, filed on Apr. 12, 2022, and Japanese Patent Application No. 2022-075145 filed on Apr. 28, 2022, are incorporated herein by reference in their entirety.

All publications, patent applications, and technical standards mentioned herein are incorporated herein by reference to the same extent as if each publication, patent application, and technical standard was specifically and individually indicated to be incorporated by reference.

1. A liquid composition, comprising:
a thermosetting resin; and
silica particles having a median diameter d50 of from 0.5 to 20.0 μm and a specific surface area of from 0.1 to 3.5 m²/g,
wherein the liquid composition has a viscosity of from 100 to 10000 mPa·s as measured at a rotation speed of 1 rpm at 25° C.

2. The liquid composition according to claim 1, further comprising a solvent, wherein the solvent comprises at least one selected from the group consisting of toluene, cyclohexanone, methyl ethyl ketone, and N-methyl-2-pyrrolidone.

3. A liquid composition, comprising:
a thermosetting resin;
silica particles having a median diameter d50 of from 0.5 to 20.0 μm, a product of a specific surface area thereof and a median diameter d50 thereof being from 2.7 to 5.0 μm·m²/g; and
a solvent having a surface tension of 45 mN/m or less.

4. The liquid composition according to claim 3, wherein the silica particles have a specific surface area of from 0.5 to 3.5 m²/g.

5. The liquid composition according to claim 3, wherein the solvent comprises at least one selected from the group consisting of toluene, cyclohexanone, methyl ethyl ketone, and N-methyl-2-pyrrolidone.

6. A liquid composition, comprising:
a thermosetting resin;
silica particles having a median diameter d50 of from 0.5 to 20.0 μm, a ratio of the median diameter d50 thereof to a 10% particle diameter d10 thereof being from more than 1.0 to 5.0; and
a solvent having a boiling point of 75° C. or more and a relative evaporation rate of from 0.3 to 4.0, the relative evaporation rate being based on an evaporation rate of butyl acetate at 23° C., which is set to 1,
wherein a thixotropy ratio, calculated by dividing a viscosity of the liquid composition measured at a rotation speed of 1 rpm by a viscosity of the liquid composition measured at a rotation speed of 60 rpm, is 3.0 or less.

7. The liquid composition according to claim 6, wherein a ratio of the median diameter d50 to the 10% particle diameter d10 of the silica particles is from 1.2 to 2.4.

8. The liquid composition according to claim 6, wherein the solvent comprises at least one selected from the group consisting of toluene, cyclohexanone, methyl ethyl ketone, and N-methyl-2-pyrrolidone.

9. A liquid composition, comprising:
a thermosetting resin; and
silica particles, wherein, in a particle size distribution obtained by a Coulter counter method, a proportion of particles having a particle diameter of 10 μm or more is 500 ppm by number or less, a coefficient of variation of particle diameter is from 30% to 80%, and a median diameter d50 is from more than 1.0 μm to 5.0 μm.

10. The liquid composition according to claim 9, wherein the silica particles have a specific surface area of from 0.1 to 5.0 m²/g.

11. The liquid composition according to claim 9, wherein the proportion of particles having a particle diameter of 10 μm or more in the silica particles is 300 ppm by number or less

12. The liquid composition according to claim 9, further comprising at least one solvent selected from the group consisting of toluene, methyl ethyl ketone, and N-methylpyrrolidone.

13. A prepreg, comprising:
the liquid composition according to claim 1 or a semi-cured product thereof; and
a fibrous substrate.

14. A prepreg, comprising:
the liquid composition according to claim 3 or a semi-cured product thereof; and
a fibrous substrate.

15. A prepreg, comprising:
the liquid composition according to claim 6 or a semi-cured product thereof; and
a fibrous substrate.

16. A prepreg, comprising:
the liquid composition according to claim 9 or a semi-cured product thereof; and
a fibrous substrate.

17. A metal substrate with a resin comprising:
the liquid composition according to claim 1 or a semi-cured product thereof; and
a metal substrate layer.

18. A metal substrate with a resin comprising:
the liquid composition according to claim 3 or a semi-cured product thereof; and
a metal substrate layer.

19. A metal substrate with a resin comprising:
the liquid composition according to claim 6 or a semi-cured product thereof; and
a metal substrate layer.

20. A metal substrate with a resin comprising:
the liquid composition according to claim 9 or a semi-cured product thereof; and
a metal substrate layer.

21. A wiring board, comprising:
a cured product of the liquid composition according to claim 1; and
a metal wiring.

22. A wiring board, comprising:
a cured product of the liquid composition according to claim 3; and
a metal wiring.

23. A wiring board, comprising:
a cured product of the liquid composition according to claim 6; and
a metal wiring.

24. A wiring board, comprising:
a cured product of the liquid composition according to claim 9; and
a metal wiring.
